(19) United States
(12) Patent Application Publication
(10) Pub. No.: US 2009/0061597 A1
(43) Pub. Date: Mar. 5, 2009

(54) SINGULATOR METHOD AND APPARATUS

(75) Inventors: Alexander S. MENDOZA, Moorpark, CA (US); Marcos NASSAR, Los Angeles, CA (US); Gary L. Casey, Thousand Oaks, CA (US)

Correspondence Address: JEFFER, MANGELS, BUTLER & MARMARO, LLP, 1900 AVENUE OF THE STARS, 7TH FLOOR, LOS ANGELES, CA, 90067, US

(73) Assignee: KAVLICO CORPORATION, Moorpark, CA (US)

(21) Appl. No.: 11/848,167

(22) Filed: Aug. 30, 2007

(51) Int. Cl. H01L 21/301

(52) U.S. Cl. 438/462; 225/17; 225/2; 225/96.5; 438/464; 257/E21.214

(57) ABSTRACT

A method for the singulation of hybrid circuits from a pre-scribed plate containing hybrid circuits or made of other brittle materials. The method includes the steps of providing a platen used to support the hybrid plate and which has a surface comprised of a series of sections each angled downward from its adjacent section, aligning the plate on the platen so that the scribe lines align with the surface discontinuities at the angles between the sections, securing the plate to the platen with vacuum pressure, creating a pressure differential between a space above the plate and a space below the plate, and applying the pressure differential to sequentially break the plate along the pre-scribed lines by forcing the plate against the angles.

### FIELD OF THE INVENTION

The present invention relates to a singulator method and apparatus, and more particularly to a method and apparatus for the singulation of brittle materials such as hybrid circuits from a pre-scribed plate.

### BACKGROUND OF THE INVENTION

Hybrid circuits are used extensively in the electronics industry, and the efficient and reliable production of such circuits is a significant factor in the manufacture of a wide array of electronic devices and components. Hybrid circuits are often produced in multiple numbers on a plate or substrate of an appropriate material, such as a ceramic.

When hybrid circuits are produced in multiple numbers on a single plate or substrate, a method must be employed to singulate the individual circuits for later use, i.e., the individual hybrid circuits must be separated from each other, aka “singulated”. Typically, the plate is scribed, often by a laser, to create lines along which the plate will later be broken. After circuits are printed, fired and populated on the plate or substrate, the plate is broken by cracking the plate along the scribe lines.

Accordingly, a need exists for a method and apparatus for singulating hybrid circuits and other brittle materials such as glass or silicon wafers that are pre-scribed.

### SUMMARY OF THE PREFERRED EMBODIMENTS

In accordance with a first preferred aspect of the present invention, there is provided a method for the singulation of hybrid circuits from a pre-scribed plate containing hybrid circuits. The method includes the steps of providing a platen used to support the hybrid plate and which has a surface comprised of a series of sections each angled downward from its adjacent section, aligning the plate on the platen so that the scribe lines align with the surface discontinuities at the angles between the sections, securing the plate to the platen with vacuum pressure, creating a pressure differential between a space above the plate and a space below the plate, and applying the pressure differential to sequentially break the plate along the pre-scribed lines by forcing the plate against the angles. No moving parts are used in the breaking of the plate and no mechanical force is applied directly to the plate. In a more preferred embodiment, the plate contains hybrid circuits arranged in strips separated by scribe lines and the angles are configured so as to break the plate into strips each containing a group of hybrid circuits. In another preferred embodiment, the plate contains hybrid circuits arranged singly in a line with each circuit separated by a scribe line, and the angles are configured so as to break the plate into individual hybrid circuits.

In accordance with another preferred aspect of the invention there is provided a hybrid circuit singulation apparatus comprising a platen for supporting and holding a plate containing hybrid circuits, a surface on the platen divided into successive sections each angled downward from its succeeding adjacent section at a predetermined position coinciding with scribe lines on the plate, and vacuum and pressure systems for holding the plate on the platen with vacuum pressure and creating a pressure differential between spaces above and below the plate sufficient to sequentially force the plate against the angle junctures of the successive platen sections and break the plate along its scribe lines. In a more preferred embodiment, the platen is of a size and configuration suitable for holding and breaking into individual strips a plate containing hybrid circuits arranged in multiple strips. In another preferred embodiment, the platen is of a size and configuration suitable for holding and breaking into individual circuits a plate containing single hybrid circuits arranged in a line.

The foregoing methodology can also be used to singulate other pre-scribed regions of brittle materials including without limitation glass and silcon wafers.

### BRIEF DESCRIPTION OF THE DRAWINGS

FIG. 1 is a perspective view of a hybrid circuit singulation apparatus, with the platen cover removed, in accordance with a preferred embodiment of the present invention;

FIG. 2 is a cross sectional view of the hybrid circuit singulation apparatus taken along line A-A of FIG. 1 and with the platen cover in place;

FIG. 3 is a cross sectional view of the hybrid circuit singulation apparatus taken along line B-B of FIG. 1 and with the platen cover in place; and

FIG. 4 is a detailed view of a section of FIG. 3.

Like numerals refer to like parts throughout the several views of the drawings.

### DESCRIPTION OF THE PREFERRED EMBODIMENTS

As shown in the drawings, for purposes of illustration, the invention is embodied in an apparatus and method for singulating hybrid circuits from a pre-scribed substrate or plate. The invention is used in any environment where there is a need to separate hybrid circuits fabricated in multiple numbers on a plate or substrate into strips of circuits or individual circuits.

It will be appreciated that terms such as “front,” “back,” “top,” “bottom,” “left,” “right,” “above,” and “side” used herein are merely for ease of description and refer to the orientation of the components as shown in the figures. It should be understood that any orientation of the singulation apparatus, and the components thereof described herein, is within the scope of the present invention.

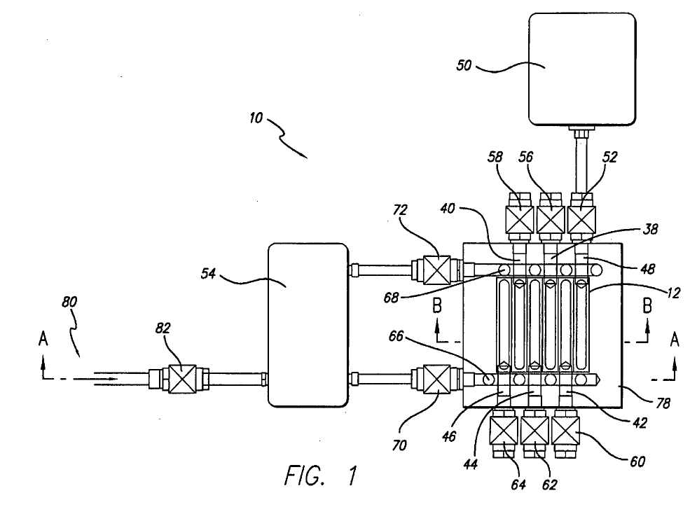

As is shown generally in FIGS. 1-4, the singulation apparatus 10 includes a platen 12 having a cover 74. In a preferred embodiment, the platen includes a surface having a series of flat sections 14, 16, 18, 20, 22, 24 each of which is provided with an associated air passage 26, 28, 30, 32, 34, 36 which couples the flat sections to associated connecting ports 38, 40, 42, 44, 46, 48 that exit the platen. One of the connecting ports 48 is connected to a vacuum source 50 through valve 52, and, in a preferred embodiment, the remaining connecting ports 38, 40, 42, 44, 46 are connected to valves 56, 58, 60, 62, 64. Additional ports 66, 68 are connected to pressure source 54 through additional valves 70, 72. Through operation of the valves, air passages 26, 28, 30, 32, 34, 38 may be made to communicate selectively with connecting ports 38, 40, 42, 44, 46, 48 and additional ports 66, 68 so as to selectively create either a vacuum or a pressurized volume in the air passages.

As is well know in the art, hybrid circuits are typically fabricated on plates or substrates in multiple numbers wherein the hybrid circuits are arranged in strips of equal width on the plate. The plates are scribed, typically by a laser, to create scribe lines along which the plate may be broken into separate strips. A typical hybrid circuit plate may be a 6×5 configuration containing 30 hybrid circuits arranged in 6 equal-width strips of 5 hybrids each. Plates of many other equal-width strip configurations are possible.

By way of illustration only, and not in any way limiting the scope of the present invention, the singulation apparatus 10 of the present invention is shown in a preferred embodiment having a configuration designed to singulate plates having 6 equal-width strips. In a preferred embodiment, a 6 strip hybrid plate 76, scribed along the edges of each strip (not shown), is placed on platen 12. The platen is shaped so that each flat surface 14, 16, 18, 20, 22, 24 is the same width as each strip of hybrids. Flat surfaces 14, 16, 18, 20, 22, 24 are angled from each other by an amount suitable to ensure a fracture of plate 76 along its scribe lines if plate 76 is pushed over the angle, but not significantly more than that value. For ceramic substrate hybrid circuit plates of about 0.025 inches thickness, it has been found that about 1.5 degrees is an adequate value for this angle. The optimal value is between about 1 and about 2 degrees for ceramic plates of about 0.025 inches. It will be understood that adequate angle values will change based upon plate thickness and composition and a wide variety of angle values are included in the preferred embodiments of the present invention without departing from the spirit and scope of the invention.

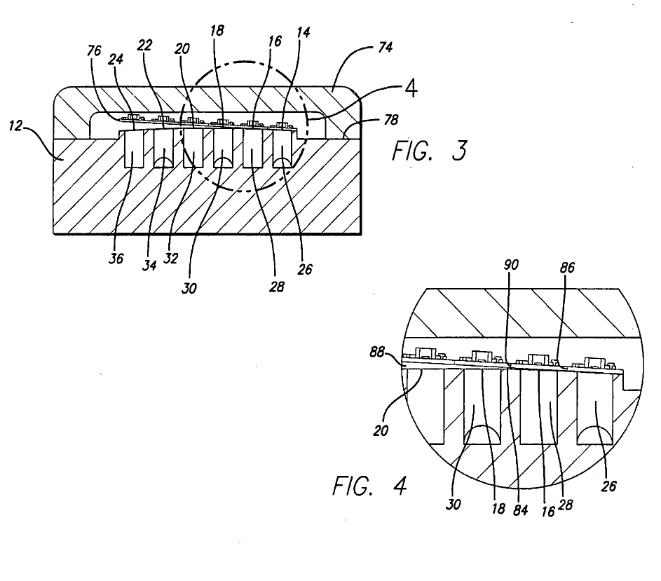

As can best be seen in FIG. 3, in a preferred embodiment air passages 26, 28, 30, 32, 34, 36 are large in area exposing most of flat surfaces 14, 16, 18, 20, 22, 24 to connecting ports 38, 40, 42, 44, 46, 48. During the singulation process plate 76 is placed on platen 12 so that the scribe line of the first strip of hybrid circuits on plate 76 is aligned with the angle between first and second flat surfaces 14, 16. Plate 76 is held in place by vacuum pressure applied to the underside of plate 76 through air passage 26 by way of vacuum source 50 through valve 52. Any conventional vacuum source may be used, with vacuum pressures from between about 10 to about 14 psi being suitable.

Cover 74 is then placed over platen 12 and brought into engagement with surface 78 of a work stage on which platen 12 rests, thereby enclosing platen 12. Cover 74 is held securely in place against surface 78 by any conventional securing means including bolts, clips, clasps, clamps, hydraulic or pneumatic rams, and the like. Pressure source 54 is then used to apply pressure inside cover 74 through additional valves 70, 72 and additional ports 66, 68. Any conventional pressure source may be used, such as a surge tank which allows a high flow of air without taxing an air supply system. If pressure source 54 is a conventional surge tank, it may be connected to an air supply 80 through a pressure regulator 82 so as to conveniently regulate the system pressure. It will be understood that the number of additional valves and additional ports may be varied from a single additional valve and port to as many as are necessary to accommodate the size of the enclosed space created by covering platen 12 with cover 74. It will also be understood that the additional valves and additional ports may be located in cover 74, as opposed to platen 12, without departing from the spirit and scope of the invention.

With cover 74 held securely in place, pressure source 54 pressurizes the enclosed space created by placing cover 74 on surface 78. While leakage at the interface between cover 74 and surface 78 is not desirable, it is not necessary to provide a perfect seal. A conventional gasket (not shown) may be used at the interface between cover 74 and surface 78.

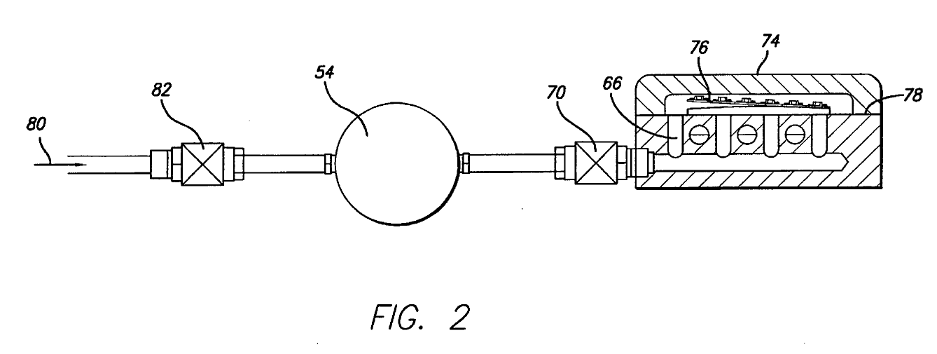

As is illustrated in the preferred embodiment shown in FIGS. 2-4, because the underside of plate 76 is flat, and because flat surfaces 14, 16, 18, 20, 22, 24 are angled away from one another, when plate 76 is held over air passage 26 by vacuum pressure, air passages 28, 30, 32, 34, 36 are uncovered. The pressurized air in the space under cover 74 escapes through air passages 28, 30, 32, 34, 36, but the flow capacity of the inlet air is sufficiently high so that the pressure above plate 76 is higher than the pressure below it. This is especially true in the areas above air passages next to where the plate is held by the vacuum.

This is shown most clearly in FIG. 4. In a preferred embodiment, when plate 76 is in its initial position held over air passage 26 by vacuum pressure, area 84 through which the pressurized air above plate 76 must flow to escape through air passage 16 is relatively small compared to air passage 16. The pressure above plate 76 then creates a force that is sufficient to break plate 76 at first scribe line 86 and the broken-off portion of plate 76 is held in place over air passage 16 by the pressurized air above it. This movement now creates another small air flow area 88 that enables sufficient pressure differential above and below plate 76 to be developed when air is forced through air passage 18 to break plate 76 at second scribe line 90. The process then proceeds sequentially across hybrid plate 76 until the plate is broken into strips at all its scribe lines.

In a preferred embodiment, at this time in the singulation process valves 56, 58, 60, 62, 64 and connecting ports 38, 40, 42, 44, 46, 48 may be used to connect air passages 14, 16, 18, 20, 22, 24 to vacuum source 50 holding the singulated strips in position over air passages 16, 18, 20, 22, 24 regardless of the pressure inside cover 74. Additional valves 70, 72 may now be closed, thereby relieving the pressure inside cover 74 at which point cover 74 may be removed. Valves 52, 56, 58, 60, 62, 64 may be used to selectively relieve the vacuum pressure holding singulated hybrid strips over air passages 14, 16, 18, 20, 22, 24, after which any conventional method may be used to pick up the strips and position them for the next operation. In another preferred embodiment, singulation apparatus 10 may omit valves 56, 58, 60, 62, 64 and not use vacuum pressure to hold singulated strips over air passages 16, 18, 20 22, 24 after completion of the singulation process.

By way of example and not by limitation on the present invention, where the angle between flat surfaces 14, 16, 18, 20, 22, 24 is 1.5 degrees, the area 84 exposed by the slot between the underside of a hybrid strip on plate 76 positioned above surface 16 and surface 16 for a plate that is 0.58 inches wide and a length of 4 inches is about 0.061 square inches. The connecting ports (for example, connecting port 42) leading away from platen 12 might have a circular diameter of approximately 0.375 inches, giving an area of about 0.11 square inches, which is about double the extent of area 84. Area 84 and connecting port 42 represent orifices in series and such orifices in series produce pressure drops that are the square of their area ratios. Accordingly, in this example the pressure drop across area 84 will be approximately 4 times that across connecting port 42. In a preferred embodiment, preferred pressures in the space enclosed by cover 74 and supplied by pressure source 54 will be between about 20 psi and about 100 psi, with a typical pressure of about 60 psi. With a pressure of about 60 psi, the force that is applied to the hybrid strip on plate 12 positioned over air passage 16 will be about 111 pounds. As is best illustrated in FIG. 4, because of the angle between the flat surfaces, in the present example, area 88 exposed by the slot between the underside of a hybrid strip on plate 76 positioned above surface 18 and surface 18 is larger than area 84 and, in this exemplary embodiment, would be approximately 0.183 square inches. Accordingly, the pressure drop across area 88 would be about 3 times that across conducting port 38, which communicates with air passage 18. This creates much less force across the hybrid strip over flat surface 18 than the preceding hybrid strip over flat surface 16. In the cited example, this force will be approximately 35 pounds, which is insufficient to cause a fracture along second scribe line 90, but sufficient to aid in the fracturing at first scribe line 86. Once fracturing has occurred along first scribe line 86, the process continues sequentially and hybrid strips are singulated off plate 76 in order, starting with the hybrid strip nearest to the initial hybrid strip held by vacuum pressure on flat surface 14.

The above description is exemplary only and does not limit the scope of the present invention in any way. For example, and as will be understood by those skilled in the art, the use of a platen having six flat sections, along with six associated air passages and connecting ports, is only exemplary and is not a limitation on the present invention which includes within its scope both smaller and larger numbers of flat sections and associated air passages and connecting ports depending upon the specific application to which the invention may be put. As will be understood from the drawings and detailed description herein, the present invention includes a platen with as few as two flat sections or as many as may be necessary to singulate plates carrying larger numbers of hybrid circuits.

The present invention also includes within its scope a platen designed to singulate into strips hybrid circuit plates containing hybrid circuits arranged in strips, as well as singulating into individual circuits hybrid circuit plates comprised of single circuits in a line. Another preferred embodiment of the present invention includes a singulation apparatus which includes multiple platens one of which is configured to singulate plates into strips and another of which is configured to singulate strips into single hybrid circuits. Use of conventional robotic arms and vacuum-holding techniques to maneuver singulated strips from one platen configured to produce singulated strips to another platen configured to produce individual singulated circuits is within the intended scope of the present invention. It will also be understood that although hybrid circuit plates are typically fabricated with circuits being placed on strips of equal width, there may be circumstances where hybrid circuit plates are fabricated with circuits being placed on strips of unequal width. Singulation of such hybrid circuits, either into strips of circuits or into individual circuits, may be accomplished by the present invention by adjusting the width of the flat surfaces on the platen so that the angles between the surfaces are aligned with the scribe lines on the plates regardless of the width of the plate strips. Accordingly, singulation of hybrid circuit plates containing hybrid circuits arranged in strips of unequal width is within the spirit and scope of the present invention.

The foregoing embodiments are merely examples of the present invention. Those skilled in the art may make numerous uses of, and departures from, such embodiments without departing from the spirit and the scope of the present invention. Accordingly, the scope of the present invention is not to be limited to or defined by such embodiments in any way, but rather, is defined solely by the following claims.

What is claimed:

1. A method of singulating hybrid circuits, the method comprising the steps of:
a. providing a platen having a top surface for the support of a plate containing hybrid circuits separated by scribed lines, wherein said top surface is divided into sections angled in relation to one another and alignable with said scribed lines;
b. using vacuum pressure to hold the plate on the platen so that the scribe lines align with the angled sections; and
c. creating a pressure differential between a space above the plate and a space below the plate and applying the pressure differential to sequentially break the plate along the scribe lines by forcing the plate against the angled sections.

2. The method of claim 1 wherein the angled sections are configured to align with scribe lines on a plate comprising hybrid circuits arranged in strips.

3. The method of claim 1 wherein the angled sections are configured to align with scribe lines on a plate comprising hybrid circuits arranged in a line.

4. The method of claim 1 wherein the angled sections comprise a first section at an edge of the platen and at least one additional section adjacent to said first section and having a surface angled lower in relation to the surface of the first section.

5. The method of claim 1 wherein the angled sections comprise a first section at an edge of the platen and a multiplicity of additional sections extending away from the first section in adjacent sequence.

6. The method of claim 5 wherein the additional sections each have a surface angled successively lower in relation to the surface of the preceding adjacent section the further each additional section is from the first section.

7. The method of claim 4 wherein the sequential breakage of the plate along the scribe lines starts at the initial flat section.

8. The method of claim 5 wherein the sequential breakage of the plate along the scribe lines starts at the initial flat section and continues in order of the additional adjacent flat sections extending away from the first section.

9. An apparatus for singulating hybrid circuits comprising:
a. a platen for supporting and holding a plate containing hybrid circuits separated by scribed lines and having a top surface divided into sections angled in relation to one another and alignable with said scribed lines, air passages within the platen connectible to one another, and conducting ports that communicate with said air passages and which extend outside said platen;
b. a vacuum system for holding said plate on said platen by creating a vacuum in said air passages;
c. a cover for covering said platen and creating a pressurizable space between the cover and said platen and its air passages and conducting ports; and
d. a pressure system for pressurizing said pressurizable space,
wherein the plate is initially held in place by said vacuum system on a first section of said platen, and wherein the angles between said sections and the configuration of said air passages and conducting ports provide for the creation by the pressure system of a pressure differential between a space above the plate and a space below the plate thereby resulting in the sequential breaking of said plate along said scribe lines against said angled sections.

10. The apparatus of claim 9 wherein said angled sections are configured to align with scribe lines on a plate comprising hybrid circuits arranged in strips.

11. The apparatus of claim 9 wherein said angled sections are configured to align with scribe lines on a plate comprising hybrid circuits arranged in a line.

12. The apparatus of claim 9 wherein the angled sections comprise a first section at an edge of the platen and at least one additional section adjacent to said first section and having a surface angled lower in relation to the surface of said first section.

13. The apparatus of claim 9 wherein the angled sections comprise a first section at an edge of the platen and a multiplicity of additional sections extending away from the first section in adjacent sequence.

14. The apparatus of claim 13 wherein the additional sections each have a surface angled successively lower in relation to the surface of the preceding adjacent section the further each additional section is from the first section.

15. The apparatus of claim 12 wherein the sequential breakage of the plate along the scribe lines starts at the initial flat section.

16. The apparatus of claim 13 wherein the sequential breakage of the plate along the scribe lines starts at the initial flat section and continues in order of the additional adjacent flat sections extending away from the first section.

17. A method of singulating pre-scribed brittle materials, the method comprising the steps of:
a. providing a platen having a top surface for the support of a plate made of brittle materials with regions of the plate separated by scribed lines, wherein said top surface is divided into sections angled in relation to one another and alignable with said scribed lines;
b. using vacuum pressure to hold the plate on the platen so that the scribe lines align with the angled sections; and
c. creating a pressure differential between a space above the plate and a space below the plate and applying the pressure differential to sequentially break the plate along the scribe lines by forcing the plate against the angled sections.

18. The method of claim 1 wherein the brittle materials comprise glass and silicon wafers.

19. An apparatus for singulating pre-scribed brittle materials, the apparatus comprising:
a. a platen for supporting and holding a plate made of a brittle material having regions separated by scribed lines and having a top surface divided into sections angled in relation to one another and alignable with said scribed lines, air passages within the platen connectible to one another, and conducting ports that communicate with said air passages and which extend outside said platen;
b. a vacuum system for holding said plate on said platen by creating a vacuum in said air passages;
c. a cover for covering said platen and creating a pressurizable space between the cover and said platen and its air passages and conducting ports; and
d. a pressure system for pressurizing said pressurizable space,
wherein the plate is initially held in place by said vacuum system on a first section of said platen, and wherein the angles between said sections and the configuration of said air passages and conducting ports provide for the creation by the pressure system of a pressure differential between a space above the plate and a space below the plate thereby resulting in the sequential breaking of said plate along said scribe lines against said angled sections.

20. The apparatus of claim 9 wherein the brittle materials comprise one or more of glass and silicon wafers.
